(19) United States
(12) Patent Application Publication
(10) Pub. No.: US 2026/0188585 A1
(43) Pub. Date: Jul. 2, 2026

(54) MULTILAYER CERAMIC ELECTRONIC COMPONENT AND CIRCUIT BOARD

(71) Applicant: TAIYO YUDEN CO., LTD., Tokyo (JP)

(72) Inventors: Takeshi SAKASHITA, Tokyo (JP); Yoshinari TAKE, Tokyo (JP); Tomoki INOUE, Tokyo (JP); Yuka NAITO, Tokyo (JP)

(73) Assignee: TAIYO YUDEN CO., LTD., Tokyo (JP)

(21) Appl. No.: 19/412,480

(22) Filed: Dec. 8, 2025

(30) Foreign Application Priority Data
Dec. 26, 2024 (JP) 2024-230171

(51) Int. Cl. H01G 4/232; H01G 4/30; H05K 1/181

(52) U.S. Cl. CPC H01G 4/232; H01G 4/30; H05K 1/181; H05K 2201/10015

(57) ABSTRACT

In a multilayer ceramic electronic component, a via conductor includes a reduced diameter extension portion extending through a protective portion to a surface thereof and having a dimension in a direction perpendicular to a stacking direction of a multilayer body that is smaller than a minimum dimension obtained in a multilayer body internal region and an enlarged diameter portion formed in the protective portion in which the reduced diameter extension portion is arranged, or in a multilayer body external region located between the protective portion in which the reduced diameter extension portion is arranged and a multilayer body internal region, the enlarged diameter portion having a dimension in a direction perpendicular to the stacking direction of the multilayer body larger than a maximum dimension obtained in the multilayer body internal region.

### CROSS-REFERENCE TO RELATED APPLICATION

This application is based upon and claims the benefit of priority of the prior Japanese Patent Application No. 2024-230171, filed on Dec. 26, 2024, the entire contents of which are incorporated herein by reference.

### FIELD

A certain aspect of the present disclosure relates to a multilayer ceramic electronic component and a circuit board.

### BACKGROUND

High-frequency communication systems, such as mobile phones, use a wide variety of ceramic electronic components. Miniaturization and thinning of these ceramic electronic components are required, and efforts are being made to achieve this goal for multilayer ceramic capacitors as well.

Japanese Patent Application Publication No. 2021-13008 (hereinafter referred to as Patent Document 1) discloses a multilayer ceramic capacitor that improves ESL characteristics and filing ratio while reducing delamination. Patent Document 1 claims that by providing a through-electrode that penetrates the body of the multilayer ceramic capacitor with a tapered, trapezoidal cross section, it is possible to improve ESL characteristics by preventing the cover from being pressed by external forces. Patent Document 1 also claims that adjusting the diameter of the through-electrode improves paste filling of vias and increases filing ratio.

Japanese Patent Application Publication No. 2005-117004 (hereinafter referred to as Patent Document 2) discloses a multilayer ceramic capacitor with reduced equivalent series inductance (ESL). In Patent Document 2, it is said that by making the columnar electrode wavy including a small diameter portion and a large diameter portion and connecting the columnar electrode to the internal electrode at the large diameter portion, the electrical and mechanical connection between the columnar electrode and the internal electrode can be ensured.

### SUMMARY OF THE INVENTION

According to an aspect of the embodiments, there is provided a multilayer ceramic electronic component including: a multilayer body having a plurality of internal electrodes facing each other in a stacking direction and ceramic layers disposed between the plurality of internal electrodes; a protective portion that covers a surface of the multilayer body; an element body having a rectangular parallelepiped shape and having a plurality of via conductors disposed to penetrate the ceramic layers in the stacking direction of the multilayer body, at least one end of which is extended to a surface of the protective portion and is electrically connected to at least a part of the plurality of internal electrodes; and a plurality of terminal electrodes, which are arranged at least on surfaces forming the surface of the element body from which ends of the via conductors are drawn out, and which are electrically connected to at least one of the plurality of via conductors; wherein the via conductor includes: a reduced diameter extension portion that extends through the protective portion to the surface of the protective portion and has a dimension in a direction perpendicular to the stacking direction of the multilayer body that is smaller than a minimum dimension obtained in a multilayer body internal region, which is a region inside a fifth internal electrode layer counted from the protective portion side of the multilayer body; and an enlarged diameter portion formed in the protective portion in which the reduced diameter extension portion is arranged, or in a multilayer body external region located between the protective portion in which the reduced diameter extension portion is arranged and a multilayer body internal region, the enlarged diameter portion having a dimension in a direction perpendicular to the stacking direction of the multilayer body larger than a maximum dimension obtained in the multilayer body internal region.

According to another aspect of the embodiments, there is provided a circuit board including: a board; and the above-mentioned multilayer ceramic electronic component mounted on the board.

### BRIEF DESCRIPTION OF THE DRAWINGS

FIG. 1 is a schematic diagram (perspective view) of a structure of a multilayer ceramic capacitor according to a first embodiment of the present invention;

FIG. 2 is an A-A cross-sectional view (LT cross-sectional view) of FIG. 1;

FIG. 3 is a diagram of a procedure for determining whether a via conductor has a reduced diameter extension portion and an enlarged diameter portion, and a procedure for determining a minimum dimension of the reduced diameter extension portion in a direction perpendicular to a stacking direction of a multilayer body, and a maximum dimension of the enlarged diameter portion in a direction perpendicular to the stacking direction of the multilayer body;

FIG. 4 is a diagram illustrating a procedure for determining whether an enlarged diameter portion of a via conductor and an end portion located in a cover portion form a flange, a procedure for determining dimensions of each portion of the via conductor, and a procedure for determining whether a dimension of the via conductor in a direction perpendicular to a stacking direction monotonically decreases within a multilayer body internal region;

FIG. 5 is a diagram illustrating a procedure for determining whether a metal element isolation portion is present near a reduced diameter extension portion in a cover portion;

FIG. 6 is a schematic diagram (LT cross-sectional view) of a structure of a multilayer ceramic capacitor including a via conductor in which a cavity opening to an end located in a protective portion (cover portion) is formed;

FIG. 7 is a diagram for explaining a procedure for determining dimensions of a cavity formed in an end of a via conductor located in a cover portion;

FIG. 8 is a schematic diagram (LT cross-sectional view) of a structure of a multilayer ceramic capacitor including a via conductor in which a center of an end located in a cover portion bulges;

FIG. 9A is a schematic diagram (LT cross-sectional view) of a multilayer ceramic capacitor including a via conductor in which a dimension in a direction perpendicular to a stacking direction of a multilayer body in a reduced diameter extension portion decreases as it approaches a surface of a cover portion, and a dimension in the direction perpendicular to the stacking direction of the multilayer body gradually increases from a multilayer body internal region side toward the reduced diameter extension portion side;

FIG. 9B is a schematic diagram (LT cross-sectional view) of a multilayer ceramic capacitor including a via conductor in which a dimension of the via conductor in a direction perpendicular to a stacking direction of a multilayer body gradually increases from a multilayer body internal region side toward a reduced diameter extension side, thereby forming an enlarged diameter portion;

FIG. 10 is a schematic diagram (LT cross-sectional view) of a structure of a multilayer ceramic capacitor according to a second embodiment of the present invention; and

FIG. 11 is a schematic diagram (perspective view) of a structure of a multilayer ceramic capacitor according to a third embodiment of the present invention.

### DETAILED DESCRIPTION

In Patent Document 1, the through electrode (via conductor) has a shape in which its diameter monotonically increases from the bottom to the top. Multilayer ceramic capacitors with via conductors of this shape suppress delamination at the interface between the via conductor and the ceramic layer, and at the interface between the via conductor and the internal electrode, as well as the decrease in electrostatic capacity caused by the disconnection between the via conductor and the internal electrode due to delamination. However, further suppression of delamination and reduction of electrostatic capacity is required.

Furthermore, unlike Patent Document 1, multilayer ceramic capacitors in which external electrodes (terminal electrodes) are formed on only one of the first or second main surfaces have a problem in that stress caused by different shrinkage behaviors between the via conductor and the terminal electrode during firing of manufacturing can easily cause delamination at the interface between the via conductor and the internal electrode, disrupting the connection between the two and resulting in a decrease in electrostatic capacity.

In the multilayer ceramic capacitor disclosed in Patent Document 2, due to the shape of the columnar electrodes (via conductors), stress tends to concentrate at the tips of the large-diameter portions and at the boundaries between the large-diameter and small-diameter portions, making the large-diameter portions susceptible to deformation or displacement due to this stress. This raises concerns that delamination may occur at the interface between the internal electrode and the ceramic layer in contact with the large-diameter portion, resulting in a decrease in electrostatic capacity.

Below, the configuration, effects, and technical concepts of the present invention will be described with reference to the drawings. However, the mechanism of action includes assumptions, and the correctness of these assumptions does not limit the present invention.

### Multilayer Ceramic Electronic Component

### First Embodiment

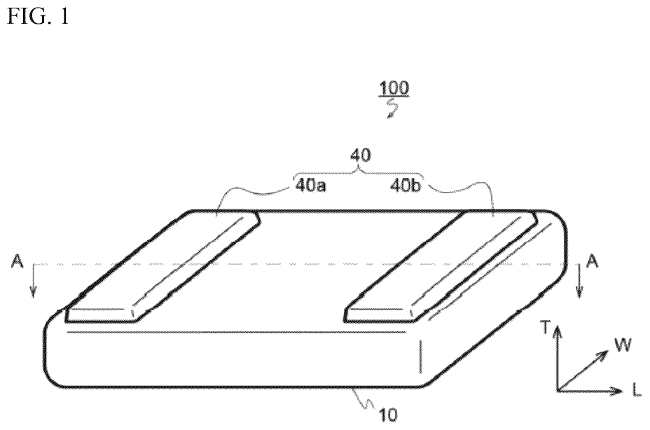

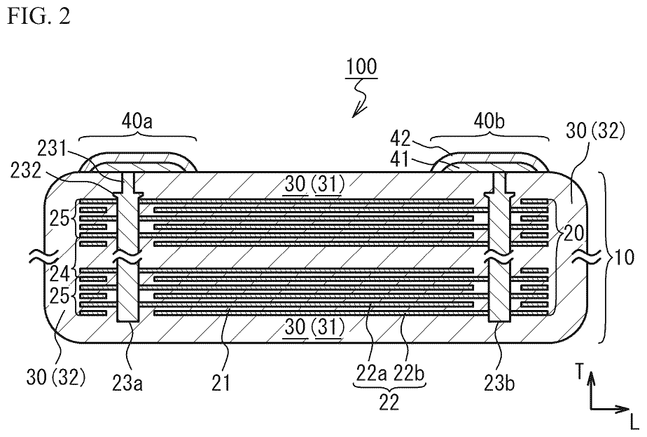

A multilayer ceramic capacitor, which is one embodiment of a multilayer ceramic electronic component according to a first aspect of the present invention, is illustrated as a first embodiment in FIG. 1 and FIG. 2. The multilayer ceramic capacitor 100 according to the first embodiment has a rectangular parallelepiped shape and includes a pair of faces orthogonal to three mutually orthogonal axes: the L-axis, which is the length direction; the W-axis, which is the width direction; and the T-axis, which is the height direction. The rectangular parallelepiped is not limited to a mathematically defined rectangular parallelepiped; any shape that can be recognized as a rectangular parallelepiped when observed as a whole is acceptable. Therefore, rectangular parallelepipeds in the present disclosure also include those with slightly rounded edges and corners, those with slightly curved edges, and those whose constituent faces are curved with a small curvature. The length (L), width (W), and height (T) dimensions of a multilayer ceramic capacitor 100 can each independently take any value.

The dimensions of the multilayer ceramic capacitor 100 include an L dimension of 200 μm or more and 2000 μm or less, a W dimension of 100 μm or more and 2000 μm or less, and a T dimension of 30 μm or more and 220 μm or less, with a W/L ratio (W to L) of 0.3 or more and 1.0 or less. Preferably, the L dimension is 400 μm or more and 1200 μm or less, the W dimension is 400 μm or more and 1200 μm or less, and the T dimension is 40 μm or more and 150μm or less, with a W/L ratio (W to L) of 0.4 or more and 1.0 or less. It is more preferable that the T-direction dimension is 100 μm or less, as this is less subject to design constraints on the circuit board on which it is mounted.

As illustrated in the cross-sectional view of FIG. 2 (LT cross section), the multilayer ceramic capacitor 100 according to the first embodiment comprises an element body 10 having a multilayer body 20 including a plurality of internal electrodes 22, each made primarily of metal and facing each other in the stacking direction (T direction), and ceramic layers 21 disposed between the plurality of internal electrodes 22, and a protective portion 30 covering the surface of the multilayer body 20. The internal electrodes 22 include internal electrodes 22a electrically connected to each other and having one polarity, and internal electrodes 22b electrically connected to each other and having the polarity opposite to that of the internal electrodes 22a.

The protective portion 30 is disposed on the surface of the element body 10, covering the surface of the multilayer body 20. The protective portion 30 includes a cover portion 31 disposed on a surface orthogonal to the T direction, and margin portions 32 disposed on surfaces orthogonal to the W direction and L direction, respectively.

The element body 10 has a plurality of via conductors 23 arranged to penetrate the ceramic layers 21 in the stacking direction of the multilayer body 20, with at least one end extending to the surface of the protective portion 30 (the cover portion 31) and electrically connected to the internal electrodes 22. The via conductors 23 include a via conductor 23a electrically connected to the internal electrode 22a and a via conductor 23b electrically connected to the internal electrode 22b. While the multilayer ceramic capacitor 100 illustrated in FIG. 1 and FIG. 2 includes two via conductors 23, the number of via conductors in the multilayer ceramic capacitor according to the first aspect of the present invention is not limited to this.

The via conductors 23 (23a, 23b) extend through the protective portion 30 (the cover portion 31) to the surface of the protective portion 30 and have a reduced diameter extension portion 231 whose dimension in a direction perpendicular to the stacking direction of the multilayer body 20 is smaller than the minimum dimension obtained in a multilayer body internal region 24, which is the region inside the fifth layer of internal electrodes 22 (22a, 22b) counting from the cover portion 31 side of the multilayer body 20. The via conductors 23 (23a, 23b) are formed in the cover portion 31 where the reduced diameter extension portion 231 is located, or in a multilayer body external region 25 located between the cover portion 31 where the reduced diameter extension portion 231 is located and the multilayer body internal region 24, and have an enlarged diameter portion 232 whose dimension in a direction perpendicular to the stacking direction of the multilayer body 20 is larger than the maximum dimension obtained in the multilayer body internal region 24. This prevents delamination at the interface between the via conductors 23 (23a, 23b) and the internal electrodes 22 (22a, 22b), thereby preventing a decrease in the electrostatic capacity of the multilayer ceramic capacitor 100. This is believed to be due to the following two points:
(1) The presence of the reduced diameter extension portion 231 reduces the contact area with the terminal electrodes 40 (40a, 40b), described below, thereby reducing the force in the stacking direction applied from the terminal electrodes 40 (40a, 40b) to the via conductors 23 (23a, 23b). Examples of such forces include those generated by differences in expansion and contraction behavior due to temperature changes during firing of manufacturing and soldering during circuit board assembly, as well as those caused by flexural deformation of the circuit board after assembly.
(2) The enlarged diameter portion 232 obstructs the relative movement of the via conductors 23 (23a, 23b) in the stacking direction relative to the ceramic layers 21, the internal electrodes 22 (22a, 22b), and the protective portion 30, thereby suppressing delamination at the interfaces between the internal electrodes 22 (22a, 22b) and the via conductors 23 (23a, 23b). Details of the shape and structure of the via conductors 23 (23a, 23b) will be described later.

The multilayer ceramic capacitor 100 according to the first embodiment includes a plurality of terminal electrodes 40 arranged at least on the surfaces forming the surface of the element body 10 from which the ends of the via conductors 23 (23a, 23b) are extended, and electrically connected to at least one of the via conductors 23 (23a, 23b). The terminal electrodes 40 include a terminal electrode 40a electrically connected to the via conductor 23a and a terminal electrode 40b electrically connected to the via conductor 23b. While the multilayer ceramic capacitor 100 illustrated in FIG. 1 and FIG. 2 includes two terminal electrodes 40, the number of terminal electrodes in the multilayer ceramic capacitor according to the first aspect of the present invention is not limited to this number.

The thickness of the element body 10, calculated by subtracting the thickness of the terminal electrodes 40 (40a, 40b) from the T-direction dimension of the multilayer ceramic capacitor 100 described above, is, for example, 20 μm or more and 200 μm or less, and preferably 30 μm or more and 180 μm or less.

The components constituting the multilayer ceramic capacitor 100 according to the first embodiment are described in detail below.

### Ceramic Layer

The ceramic layer 21 is formed of ceramic. The ceramic composition is not particularly limited as long as it forms the dense ceramic layer 21 by co-firing with the internal electrodes 22, described below, and may be selected appropriately depending on the characteristics required of the multilayer ceramic capacitor. The ceramic composition is such as those primarily composed of barium titanate (BaTiO₃), those primarily composed of strontium titanate (SrTiO₃), or those primarily composed of Ba_{1-x-y}CaₓSr_{y}Ti_{1-z}Zr_{z}O₃ having a perovskite structure. The ceramic may contain additive elements in addition to the primary components. The additive element is such as Mo, Nb, Ta, W, Mg, Mn, V, Cr, or a rare earth element (Y, Sm, Eu, Gd, Tb, Dy, Ho, Er, Tm, or Yb), as well as at least one selected from Co, Ni, Li, B, Na, K, or Si. The additive element may be contained as a simple element or in the form of compound such as oxide, nitride, or carbide. The additive element may be present in the form of a solid solution in the main component, or may form a different phase from the element constituting the main component or another additive element.

### Internal Electrode

The internal electrodes 22 (22a, 22b) are primarily composed of a metal. The type of metal is not particularly limited, and nickel (Ni), copper (Cu), palladium (Pd), platinum (Pt), silver (Ag), gold (Au), or an alloy including one of them can be used. Among these, nickel (Ni) is preferred as its primary element because of its high heat resistance, which allows for a high firing temperature during co-firing with the ceramic layer 21 to form the dense ceramic layer 21, and its relative low cost. Here, “primary element” in this specification refers to the element with the highest content, expressed in atomic percentage (atomic %).

In addition to metal, the internal electrodes 22 (22a, 22b) may also contain ceramic grains having a composition similar to that of the ceramic constituting the ceramic layer 21, or glass components.

### Multilayer Body

The multilayer body 20 has the plurality of internal electrodes 22 (22a, 22b) facing each other in the stacking direction and the ceramic layers 21 disposed between the plurality of internal electrodes 22 (22a, 22b). The multilayer body 20 has the multilayer body internal region 24 located inside the fifth internal electrode 22 (22a, 22b) counting from the outermost layer in the stacking direction, and the multilayer body external region 25 located outside the multilayer body internal region 24 in the stacking direction.

### Protective Portion

The protective portion 30 functions to protect the ceramic layers 21 and the internal electrodes 22. There are no restrictions on the material of the protective portion 30, as long as it has high electrical insulation and low permeability to moisture and other degradation factors. From the perspectives of ensuring uniform shrinkage during firing and mitigating internal stress within the multilayer ceramic capacitor 100 when manufacturing the multilayer ceramic capacitor 100, it is preferable that the main component of the protective portion 30 is the same as the ceramic that forms the ceramic layers 21.

In the protective portion 30, the cover portion 31 through which the reduced diameter extension portion 231 of the via conductor 23 (23a, 23b) described below passes preferably has a metal element isolation portion 311 near the reduced diameter extension portion 231, in which the concentration of the same metal element as the main component element of the via conductor 23 (23a, 23b) is higher than in the surrounding area. This brings the mechanical and thermal properties of the cover portion 31 located around the reduced diameter extension portion 231 closer to the properties of the reduced diameter extension portion 231, thereby suppressing delamination at the interface between the reduced diameter extension portion 231 and the cover section 31. A method for determining whether or not the metal element isolation portion 311 exists near the reduced diameter extension portion 231 will be described later.

### Via Conductor

Like the internal electrodes 22 (22a, 22b), the via conductors 23 (23a, 23b) are primarily composed of metal. Usable metals include those similar to those used for the internal electrodes 22 (22a, 22b) described above. The metal composition of the via conductors may be different from that of the internal electrodes 22 (22a, 22b), but is preferably the same as that of the internal electrodes 22 (22a, 22b). By using the same metal composition for the via conductors (23a, 23b) and the internal electrodes 22 (22a, 22b), the magnitude of shrinkage caused by firing during the manufacturing of the multilayer ceramic capacitor 100 is consistent, suppressing deformation. Furthermore, the resistivity of the conductive paths of the multilayer

As described above, the via conductors 23 (23a, 23b) have the reduced diameter extension portion 231 and the enlarged diameter portion 223. The reduced diameter extension portion 231 extends through the cover portion 31 to the surface of the cover portion 31, and is a portion whose dimension in a direction perpendicular to the stacking direction of the multilayer body 20 is smaller than the smallest dimension obtained in the multilayer body internal region 24. The enlarged diameter portion 232 is formed in the cover portion 31 where the reduced diameter extension portion 231 is located, or in the multilayer body external region 25 adjacent to the cover portion 31 where the reduced diameter extension portion 231 is located, and is a portion whose dimension in a direction perpendicular to the stacking direction of the multilayer body 20 is larger than the largest dimension obtained in the multilayer body internal region 24.

It is preferable that the largest dimension of the enlarged diameter portion 232 of the via conductor 23 (23a, 23b) in the direction perpendicular to the stacking direction of the multilayer body 20 is 1.2 times or more the smallest dimension of the reduced diameter extension portion 231 in the direction perpendicular to the stacking direction of the multilayer body 20. This significantly suppresses the relative movement of the via conductors 23 (23a, 23b) in the stacking direction relative to the ceramic layers 21, the internal electrodes 22 (22a, 22b), and the protective portion 30. The maximum dimension is preferably 1.5 times or more, and even more preferably 2.0 times or more, of the smallest dimension.

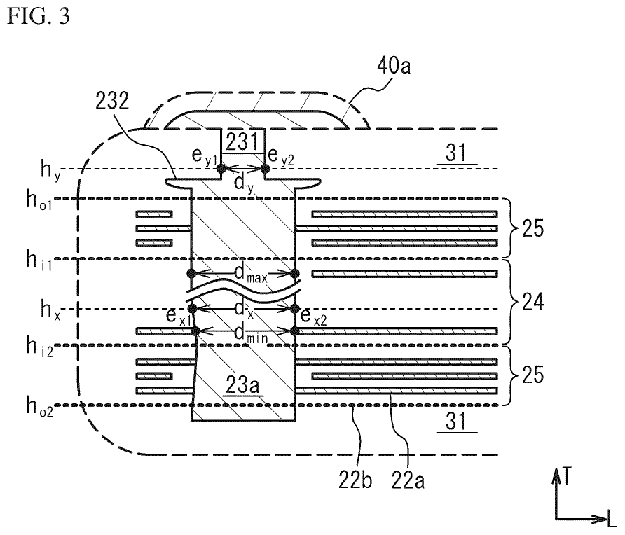

The determination of whether the via conductors 23 (23a, 23b) have the reduced diameter extension portion 231 and the enlarged diameter portion 232, as well as the determination of the smallest dimension of the reduced diameter extension portion 231 in the direction perpendicular to the stacking direction of the multilayer body 20 and the largest dimension of the enlarged diameter portion 232 in the direction perpendicular to the stacking direction of the multilayer body 20, are performed using the following procedures. First, the multilayer ceramic capacitor 100 is cut or ground along a plane parallel to the stacking direction of the multilayer body 20 using a focused ion beam (FIB) device or a cross-section polisher (registered trademark) (CP) to expose the vicinity of the center of gravity of the via conductor 23 (23a, 23b) to be evaluated. Cutting or grinding may be performed on the multilayer ceramic capacitor 100 embedded in resin. The following describes a case where the via conductor 23a is the evaluation target. Next, the surface where the via conductor 23a is exposed is observed with a scanning electron microscope (SEM) equipped with an energy dispersive X-ray spectrometer (EDS). A region to be measured is determined to include one end of the via conductor 23a that is extended to the surface of the cover portion 31, as well as portions located near the via conductor 23a to be evaluated of the cover portion 31 and the multilayer body 20 through which the via conductor 23a to be evaluated penetrates. Next, the region to be measured is analyzed using EDS, and a mapping image of the main component element of the via conductor 23a and the internal electrodes 22 (22a, 22b), or the main component elements common to the ceramic layer 21 and the cover portion 31, as illustrated in FIG. 3, is obtained. Note that FIG. 3 also illustrates the analysis results for Ni, which is the main component element of the via conductor 23a. Next, in the obtained mapping image, the shapes of the internal electrodes 22 (22a, 22b) located in the outermost layer in the stacking direction of the multilayer body 20 are linearly approximated to line segments having the same thickness as their thicknesses, thereby drawing the line segments hₒ₁ and hₒ₂. Next, in the mapping image, the shapes of the internal electrodes 22 (22a, 22b) in the fifth layer counting from the outermost layer in the stacking direction of the multilayer body 20 are linearly approximated to line segments having the same thickness as their thicknesses, thereby drawing the line segments hᵢ₁ and hᵢ₂. The region sandwiched between the line segments hᵢ₁ and hᵢ₂ is defined as the multilayer body internal region 24, and the region sandwiched between the line segments hₒ₁ and hᵢ₁ and the region sandwiched between the line segments hₒ₂ and hᵢ₂ are defined as the multilayer body external region 25. Next, in the mapping image, a line segment hₓ parallel to the line segment hᵢ₂ is drawn in the multilayer body internal region 24, and the two points where the line segment hₓ intersects with the boundary line between the via conductor 23a to be determined and the multilayer body 20 are defined as points eₓ₁ and eₓ₂. This line segment hₓ is drawn at various positions, and the distance dₓ between the point eₓ₁ and the point eₓ₂ is measured, and the longest of the obtained distances is defined as dₘₐₓ, and the shortest is defined as dₘᵢₙ. Next, in the mapping image, a line segment h_{y} parallel to the line segment hᵢ₁ is drawn on the cover portion 31 where the end of the via conductor 23a to be evaluated is extended to the surface, and the two points where the line segment h_{y} intersects with either the boundary line between the via conductor 23a to be evaluated and the multilayer body 20 or the boundary line between the via conductor 23a to be evaluated and the cover portion 31 are designated as points e_{y1} and e_{y2}. This line segment h_{y} is drawn at various positions, and the distance d_{y} between the points e_{y1} and e_{y2} is measured. If the obtained d_{y} always satisfies d_{y} <dₘᵢₙ on the surface side from a certain position, the via conductor 23a to be evaluated is determined to have the reduced diameter extension portion 231. Furthermore, if there is a position where dₘₐₓ <d_{y}, the via conductor 23a to be evaluated is determined to have the enlarged diameter portion 232. The minimum value of d_{y} obtained is divided by the SEM magnification to determine the minimum dimension of the reduced diameter extension portion 231 in the direction perpendicular to the stacking direction of the multilayer body 20, and the maximum value of d_{y} obtained is divided by the SEM magnification to determine the maximum dimension of the enlarged diameter portion 232 in the direction perpendicular to the stacking direction of the multilayer body 20.

The enlarged diameter portion 232 of the via conductor 23 (23a, 23b) preferably forms a flange that extends outward relative to the axis of the via conductor 23 (23a, 23b). This allows the diameter of most of the via conductors 23 (23a, 23b) passing through the multilayer body 20 to be reduced, thereby increasing the area of the internal electrodes 22 (22b, 22a) that are formed so as not to be electrically connected to the via conductors 23 (23a, 23b), and thereby increasing the electrostatic capacity of the multilayer ceramic capacitor 100.

When the enlarged diameter portion 232 forms a flange, the thickness of the flange, that is, the dimension A1 in the stacking direction, is preferably 0.1 μm or more and 10 μm or less. Having a flange thickness of 0.1 μm or more formed by the enlarged diameter portion 232 ensures sufficient resistance to suppress the relative displacement of the via conductors 23 (23a, 23b) in the stacking direction, as described above. On the other hand, having a flange thickness of 10 μm or less reduces the number of the internal electrodes 22 (22b, 22a), the area of which is reduced to avoid contact with the flange, thereby increasing the electrostatic capacity of the multilayer ceramic capacitor 100.

Preferably, the ends of the via conductors 23 (23a, 23b) opposite the reduced diameter extension portion 231 are disposed within the protective portion 30 (the cover portion 31), and the opposite ends form a flange that protrudes outward relative to the axis of the via conductor. This further increases the resistance of the via conductors 23 (23a, 23b) to relative displacement in the stacking direction, as described above, and significantly suppresses the decrease in electrostatic capacity of the multilayer ceramic capacitor 100.

When the dimension of the via conductors 23 (23a, 23b) in the direction perpendicular to the stacking direction of the multilayer body 20 at the end of the multilayer body internal region 24 on the side of the reduced diameter extension portion 231 is D1, and the dimension of the via conductors 23 (23a, 23b) in the direction perpendicular to the stacking direction of the laminate 20 at the end of the multilayer body internal region 24 on the opposite side from the reduced diameter extension portion 231 is D2, it is preferable that D1 >D2, and that the dimension in the direction perpendicular to the stacking direction monotonically decreases from D1 to D2. This effectively suppresses delamination at the interface between the via conductors 23 (23a, 23b) and the internal electrodes 22 (22a, 22b), further suppressing the decrease in electrostatic capacity of the multilayer ceramic capacitor 100. This is presumably due to the tapered shape of the via conductors 23 (23a, 23b), which increases the contact area with the multilayer body 20 and increases frictional resistance.

In this case, if the dimension perpendicular to the stacking direction of the flange formed by the end portion located inside the cover portion 31 is D3 and the via conductors 23 (23a, 23b) satisfies D3 ≥D1, the delamination at the interface between the via conductors 23 (23a, 23b) and the internal electrodes 22 (22a, 22b) is more effectively suppressed, further suppressing a decrease in electrostatic capacity of the multilayer ceramic capacitor 100. This is presumably due to the fact that the large dimension of the flange in the direction perpendicular to the stacking direction significantly increases the resistance force when the above-mentioned via conductors 23 (23a, 23b) are displaced relative to the stacking direction.

The values of D1, D2, and D3 are not particularly limited, but in order to ensure the electrostatic capacity of the multilayer ceramic capacitor 100 while reducing electrical resistance and suppressing heat generation during circuit operation, the value of D2 is preferably 5 μm or more and 100 μm or less, and more preferably 10 μm or more and 50 μm or less. Furthermore, the value of D3 is preferably 110% or more and 225% or less of the value of D2, and more preferably 150% or more and 180% or less of the value of D2. Furthermore, the value of D3 is preferably 100% or more and 150% or less of the value of D1, and more preferably 100% or more and 120% or less of the value of D1.

It is preferable that the via conductors 23 (23a, 23b) have the flange formed by the end located inside the cover portion 31, whose dimension in the stacking direction, i.e., the thickness A2 of the flange, is 0.1 μm or more and 10 μm or less. Having the flange thickness of 0.1 μm or more ensures sufficient resistance to suppress displacement of the via conductors 23 (23a, 23b) in the stacking direction. On the other hand, having the flange thickness of 10 μm or less ensures sufficient distance from the surface of the element body 10 and the internal electrode 22 to the via conductors 23 (23a, 23b), ensuring the reliability of the multilayer ceramic capacitor 100.

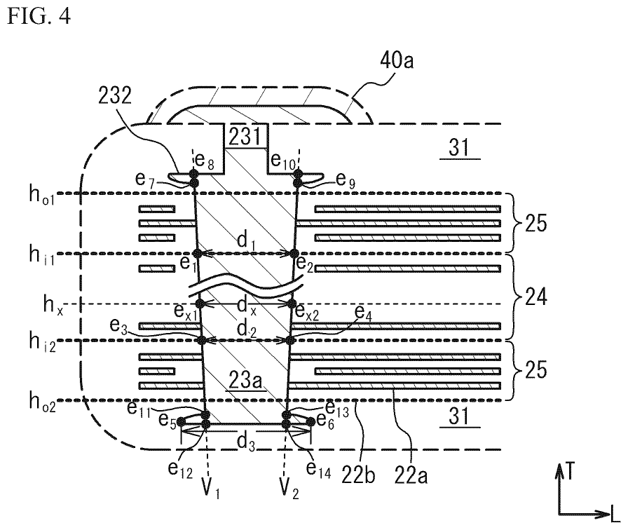

Here, the following procedures are used to determine whether the enlarged diameter portion 232 of the via conductor 23 (23a, 23b) and the end portion located within the cover portion 31 form the flange, to determine the dimensions D1, D2, D3, A1, and A2 of each portion of the via conductor 23 (23a, 23b), and to determine whether the dimension of the via conductor 23 (23a, 23b) monotonically decreases from D1 to D2. First, similar to the procedure for determining whether the via conductor 23 (23a, 23b) has the reduced diameter extension portion 231 and the enlarged diameter portion 232 described above, a mapping image is acquired, and the line segments hₒ₁, hₒ₂, hᵢ₁, hᵢ₂, and hₓ, as well as the points eₓ₁ and eₓ₂, are drawn in the mapping image. In this case, the line segments hₒ₁ and hᵢ₁ are drawn on the side closer to the enlarged diameter portion 232 of the via conductor 23 (23a, 23b), and the line segments hₒ₂ and hᵢ₂ are drawn on the side closer to the end of the via conductor 23 (23a, 23b) located in the cover portion 31. Next, in the mapping image, as illustrated in FIG. 4, the line segments v₁ and v₂ are drawn, respectively, defining both side surfaces of the portion of the via conductor 23a to be determined that is located in the multilayer body internal region 24. Then, the enlarged diameter portion 232 is determined to form a flange when the enlarged diameter portion 232 exists beyond the line segments v₁ and v₂ outward from the axis of the via conductor 23a. Similarly, the end of the via conductor 23a located in the cover portion 31 is determined to form a flange when the end exists beyond the line segments v₁ and v₂ outward from the axis of the via conductor 23a. Next, in the mapping image, the intersection e₁ between the line segment hᵢ₁ and the line segment v₁ and the intersection e₂ between the line segment hᵢ₁ and the line segment v₂ are drawn, and the distance d₁ between the point e₁ and the point e₂ is divided by the SEM observation magnification to obtain D1. Next, in the mapping image, the intersection e₃ between the line segment hᵢ₂ and the line segment v₁ and the intersection e₄ between the line segment hᵢ₂ and the line segment v₂ are drawn, and the distance d₂ between the point e₃ and the point e₄ is divided by the SEM observation magnification to obtain D2. At this time, as the line segment hₓ approaches the line segment hᵢ₁ from the line segment hᵢ₂, the distance dₓ between the point eₓ₁ and the point eₓ₂ monotonically decreases from d₁ to d₂, and it is determined that the dimension of the via conductor 23a monotonically decreases from D1 to D2. Next, in the mapping image, the point e₅, which is the farthest point from the axis of the via conductor 23a toward the line segment v₁, and the point e₆, which is the farthest point from the axis of the via conductor 23a toward the line segment v₂, are drawn in the cover portion 31 containing the end of the via conductor 23a. The distance d₃ between the points e₅ and e₆ is divided by the SEM magnification, and this value is defined as D3. Next, in the mapping image, the points e₇ and e₈ are drawn at two points where the enlarged diameter portion 232 intersects with the line segment v₁, and the points e₉ and e₁₀ are drawn at two points where the enlarged diameter portion 232 intersects with the line segment v₂. The point e₇ is drawn closer to the multilayer body 20 than the point e₈, and the point e₉ is drawn closer to the multilayer body 20 than the point e₁₀. The average of the distance between the points e₇and e₈ and the distance between the points e₉ and e10 is divided by the SEM magnification, and this value is defined as A1. Next, in the mapping image, the points e₁₁ and e₁₂ are drawn at two points where the end of the via conductor 23a located in the cover portion 31 intersects with the line segment v₁, and the points e₁₃ and e₁₄ are drawn at two points where the end of the via conductor 23a located in the cover portion 31 intersects with the line segment v₂. The point e₁₁ is drawn closer to the multilayer body 20 than the point e₁₂, and the point e₁₃ is drawn closer to the multilayer body 20 than the point e₁₄. The average of the distance between the points e₁₁ and e₁₂ and the distance between the points e₁₃ and e₁₄ is divided by the SEM observation magnification to obtain A2. When drawing the line segments v₁ and v₂, if the side surface of the via conductor 23a observed in the mapping image forms a curve or a polygonal line, the curve or the polygonal line is linearly approximated to form the line segment. Furthermore, while the above-described procedure applies to the vicinity of the via conductor 23a, it goes without saying that it may also be performed in the vicinity of the via conductor 23b, which has a different polarity.

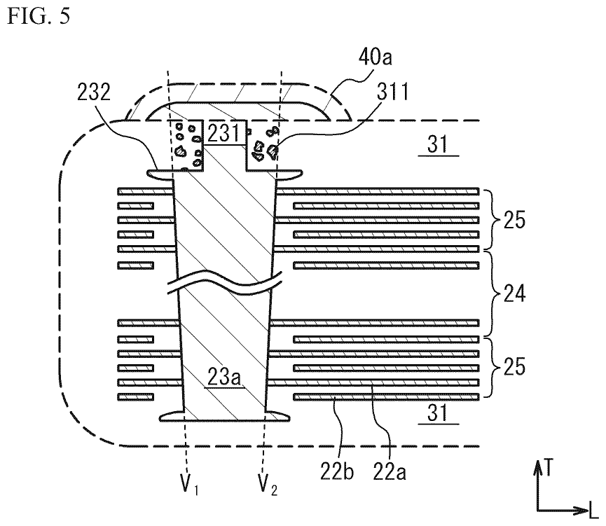

Furthermore, the presence of the metal element isolation portion 311 in the vicinity of the reduced diameter extension portion 231 in the cover portion 31, which is described above as a preferred embodiment of the cover portion 31, is determined by the following procedure. First, similar to the procedure for determining whether the via conductor 23 (23a, 23b) has the reduced diameter extension portion 231 and the enlarged diameter portion 232, a mapping image is obtained, and the line segments v₁ and v₂ are respectively drawn in the mapping image, as illustrated in FIG. 5. Next, in the mapping image, island-like regions with a high concentration of the same metal element as the main component element of the via conductor 23 (23a, 23b) are observed in the region located between line segment v₁ and the reduced diameter extension portion 231, and in the region located between line segment v₂ and the reduced diameter extension portion 231, respectively, and it is determined that metal element isolation portion 311 exists near the reduced diameter extension portion 231 in the cover portion 31.

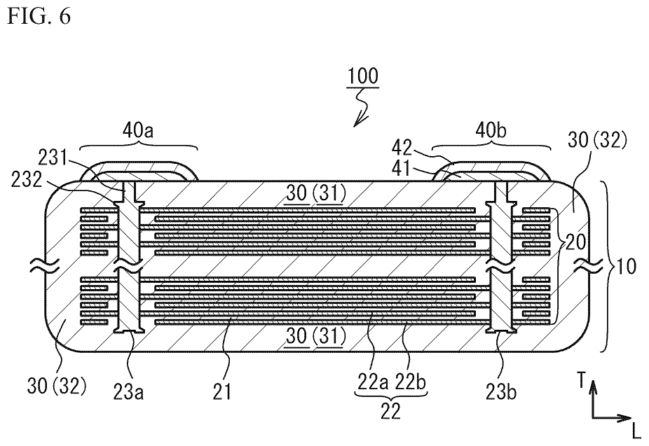

As illustrated in FIG. 6, it is preferable that via conductor 23 (23a, 23b) further has an opening cavity formed at the end forming the flange located in the cover portion 31. This suppresses delamination at the interface between the via conductor 23 (23a, 23b) and the cover portion 31 in the cover portion 31 that includes the end of the via conductor 23 (23a, 23b) therein. This is presumably because the presence of the cavities reduces the contact area between the via conductors 23 (23a, 23b) and the cover portion 31, thereby reducing the stress generated at the interface between the via conductors 23 (23a, 23b) and the cover portion 31 due to the difference in the amount of shrinkage between them during firing during manufacturing.

More preferably, the maximum dimension D4 of the cavities formed at the ends of the via conductors 23 (23a, 23b) located within the cover portion 31 in the direction perpendicular to the stacking direction of the multilayer body 20 is 10% to 90% of the above-mentioned D2, that is, the dimension of the end of the multilayer body internal region 24 opposite the reduced diameter extension portion 231 in the direction perpendicular to the stacking direction of the multilayer body 20. Having D4 at least 10% of D2 significantly suppresses delamination at the interface between the via conductors 23 (23a, 23b) and the cover portion 31. On the other hand, by making D4 90% or less of D 2, the resistance of the via conductors 23 (23 a, 23 b) to displacement in the stacking direction and in a direction perpendicular to the stacking direction is sufficient, thereby suppressing delamination at the interface between the via conductors 23 (23a, 23b) and the internal electrodes 22 (22a, 22b).

The maximum dimension A3 in the stacking direction of the cavity formed at the end of the via conductor 23 (23a, 23b) located within the cover portion 31 is preferably 1 μm or more and 20 μm or less, more preferably 1 μm or more and 10 μm or less, and even more preferably 1 μm or more and 5 μm or less. Having A 3 of 1 μm or more significantly suppresses delamination at the interface between the via conductor 23 (23a, 23b) and the cover portion 31. On the other hand, having A3 of 10 μm or less provides sufficient resistance to displacement of the via conductor 23 (23a, 23b) in the stacking direction and in the direction perpendicular to the stacking direction, thereby suppressing delamination at the interface between the via conductor 23 (23a, 23b) and the internal electrode 22 (22a, 22b).

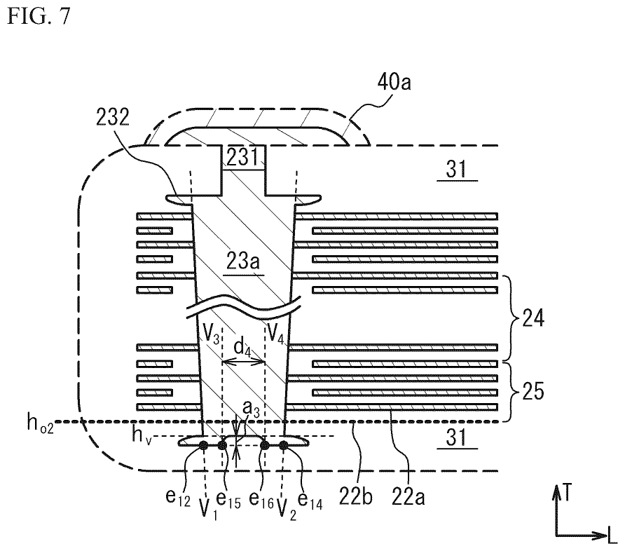

Here, the dimensions D4 and A3 of each part of the cavity formed at the end of the via conductor 23 (23a, 23b) located inside the cover portion 31 are determined using the following procedure. First, a mapping image is obtained using the same procedure as when determining the dimensions D1, D2, D3, A1, and A2 above. In the mapping image, line segments hₒ₂, v₁, and v₂, as well as points e₁₂ and e₁₄, are drawn, as illustrated in FIG. 7. Next, in the mapping image, a line segment e₁₂e₁₄ is drawn connecting the points e₁₂ and e₁₄. Of the points where the line segment e₁₂e₁₄ intersects with the outline of the via conductor 23a that defines the cavity at the end of the via conductor 23a located inside the cover portion 31, the point closest to the point e₁₂ is designated e₁₅, and the point closest to the point e₁₄ is designated e₁₆. In this case, if the point e₁₅ does not exist, the point e₁₂ is treated as the point e₁₅ in subsequent operations, and if the point e₁₆ does not exist, the point e₁₄ is treated as the point e₁₆ in subsequent operations. Next, in the image, a line segment v₃ passing through the point e₁₅ and perpendicular to the line segment hₒ₂, and a line segment v₄ passing through the point e₁₆ and perpendicular to the line segment hₒ₂ are drawn, and the value obtained by dividing the distance d₄ between the line segments v₃ and v₄ by the magnification of the microscope image is defined as D4. Next, in the mapping image, a line segment hᵥ is drawn that is parallel to the line segment hₒ₂, touches the outline of the via conductor 23a that defines the cavity, and is the greatest distance from the line segment e₁₂e₁₄, and the value obtained by dividing the shortest distance a₃ between the line segments hᵥ and e₁₂e₁₄ by the observation magnification of the SEM is defined as A3.

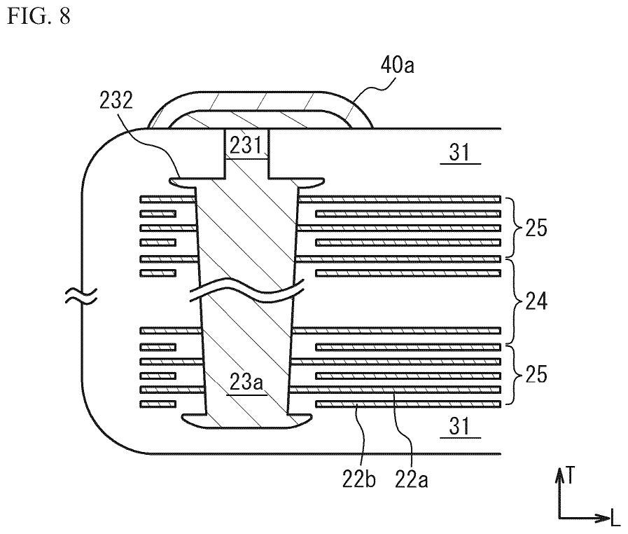

The ends of the via conductors 23 (23a, 23b) located within the protective portion 30 (the cover portion 31) may have a centrally bulged shape, as illustrated in FIG. 8, that is, a shape with a convex portion protruding in the stacking direction of the multilayer body 20, as opposed to the hollow shape described above. This shape is formed when, during the manufacturing process of the multilayer ceramic capacitor 100 described below, the conductive paste used to form the via conductors remains without migrating toward the reduced diameter extension portion 231 and pushes back the green sheet used to form the cover portion when the green sheet is compressed. Therefore, the centrally bulged ends of the via conductors 23 (23a, 23b) located within the cover portion 31 indicate strong adhesion between the via conductors 23 (23a, 23b) and the adjacent cover portion 31, the ceramic layer 21, and the internal electrode 22 (22a, 22b), resulting in the multilayer ceramic capacitor 100 with high mechanical strength.

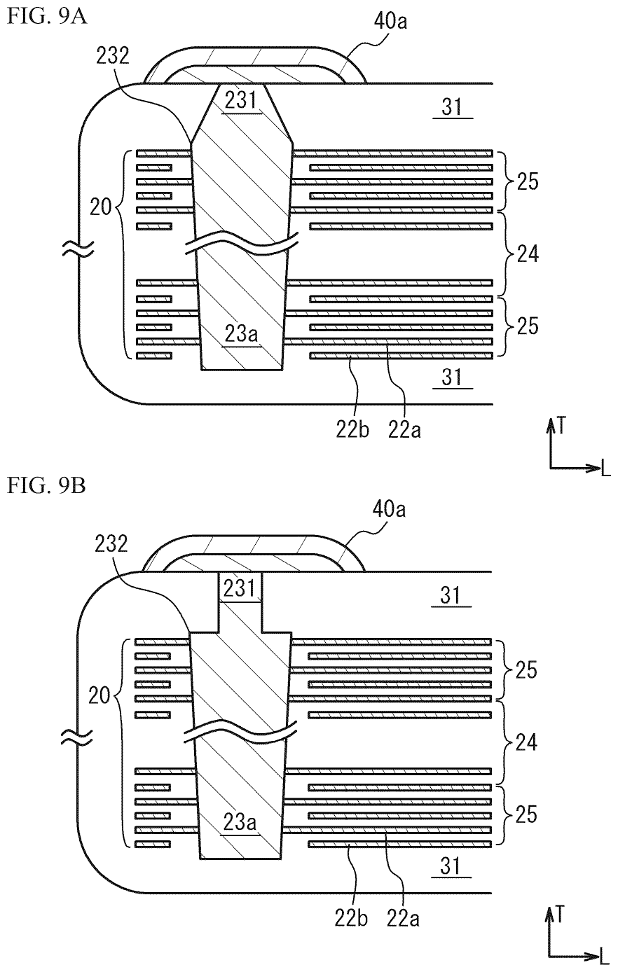

Although FIG. 2 to FIG. 8 illustrate the via conductors 23 (23a, 23b) in which the reduced diameter extension portion 231 has a substantially constant dimension in the direction perpendicular to the multilayer body 20 and the enlarged diameter portion 232 forms a flange, the shape of the via conductors 23 (23a, 23b) is not limited to this. For example, as illustrated in FIG. 9A, the dimension of the reduced diameter extension portion 231 in the direction perpendicular to the stacking direction of the multilayer body 20 may decrease as it approaches the surface of the cover portion 31. Also, as illustrated in FIG. 9A and FIG. 9B, the dimension of the via conductors 23 (23a, 23b) in the direction perpendicular to the stacking direction of the multilayer body 20 may gradually increase from the multilayer body internal region 24 toward the reduced diameter extension portion 231, thereby forming the enlarged diameter portion 232.

### Terminal Electrode

The material of the terminal electrodes 40 (40a, 40b) is not limited as long as it is electrically conductive. The material is such as nickel (Ni), copper (Cu), tin (Sn), palladium (Pd), platinum (Pt), silver (Ag), or gold (Au), alloys containing any of these as the main component element, and conductive resins.

The terminal electrode 40 (40a, 40b) may have a base conductor 41 in contact with the element body 10 and a plated conductor 42 formed on the surface of the base conductor 41. The terminal electrode 40 (40a, 40b) with this structure can improve adhesion to the element body 10 through the base conductor 41, while improving solder wettability during circuit board mounting through the plated conductor 42.

An example of a material for the base conductor 41 is Ni. The thickness of the base conductor 41 may be 0.1 μm or more and 10 μm or less, and preferably 0.5 μm or more and 5μm or less.

The plated conductor 42 may be formed of a single layer or multiple layers. If the plated conductor 42 is formed of multiple layers, the number of layers is preferably two to four. The plated conductor 42 may be made of Cu, Ni, and Sn, in this order, for example. The thickness of the plated conductor 42 may be 1 μm or more and 20 μm or less, and preferably 3 μm or more and 10μm or less.

### Second Embodiment

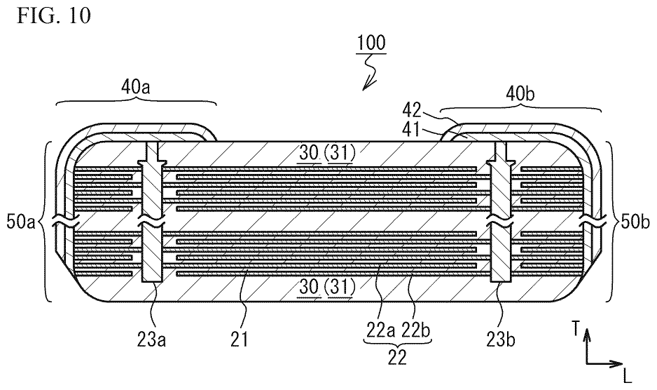

In another embodiment (second embodiment) of the multilayer ceramic capacitor according to the first aspect of the present invention, internal electrodes are extended on a surface perpendicular to the surface on which the ends of the via conductors 23 (23a, 23b) of the element body 10 are extended, and external electrodes are disposed on the surfaces on which the internal electrodes are extended (internal electrode extension surfaces). Electrical connection between the internal electrodes is also achieved via the external electrodes. An example of a multilayer ceramic capacitor 200 according to the second embodiment is illustrated in FIG. 10. While FIG. 10 illustrates an example in which two opposing surfaces are internal electrode extension surfaces, the number of internal electrode extension surfaces is not limited to this. Additionally, while FIG. 10 illustrates an example in which the terminal electrodes 40 (40a, 40b) extending to the internal electrode extraction surface form external electrodes 50 (50a, 50b), the external electrodes 50 (50a, 50b) may be formed separately from the terminal electrodes 40 (40a, 40b). In the multilayer ceramic capacitor 200, the current flowing through the internal electrodes 22 (22a, 22b) is divided into the via conductors 23 (23a, 23b) and the external electrodes 50 (50a, 50b), thereby reducing the current flowing through each of the via conductor 23 (23a, 23b) and the external electrode 50 (50a, 50b). This reduces heat generation during operation.

### Third Embodiment

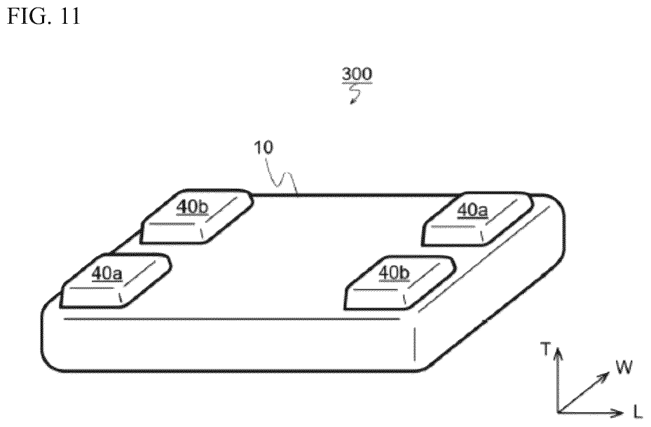

In another embodiment (third embodiment) of the multilayer ceramic capacitor according to the first aspect of the present invention, the number of terminal electrodes arranged on one surface of the element body is four or more, and each terminal electrode has a polarity opposite to that of the nearest adjacent terminal electrode within the surface. An example of a multilayer ceramic capacitor 300 according to the third embodiment is illustrated in FIG. 11. Note that while FIG. 11 illustrates an example in which the four terminal electrodes 40 are arranged on one surface of the element body 10, the number of the terminal electrodes arranged on one surface of the element body 10 is not limited to this. In the multilayer ceramic capacitor 300, the currents flowing through the via conductors (not illustrated) electrically connected to each of the terminal electrodes 40 (40a, 40b) are opposite to each other in the nearest adjacent conductors. This results in the magnetic fields generated by the currents canceling each other out, thereby reducing equivalent series inductance (ESL). The above-described effects are remarkable when the multilayer ceramic capacitor 300 has two pairs of surfaces that are parallel to the stacking direction of the multilayer body and face each other, with the spacing between one pair, i.e., the dimension in the L direction, being L μm and the spacing between the other pair, i.e., the dimension in the W direction, being W μm (where L≥W), and the value of W/L, which is the ratio of W to L, is 0.8 or more and 1 or less, i.e., when the surfaces on which the terminal electrodes are arranged have a shape that is close to a square.

### Method for Manufacturing Multilayer Ceramic Electronic Components

The multilayer ceramic capacitor according to the first aspect of the present invention can be manufactured according to the following procedure.

### (A) Preparation of Ceramic Powder

First, ceramic powder is prepared. Commercially available ceramic powders may be used as appropriate. To making ceramic powder, various raw material powders containing the constituent elements are mixed in a predetermined ratio and pre-fired (calcined). When mixing the raw material powders in a predetermined ratio, various additives such as the aforementioned additive elements and sintering aids may be added. These additives may also be added to the pre-fired powder.

### (B) Preparation of Green Sheet

Next, the aforementioned ceramic powder is mixed with a binder and a dispersant to prepare a slurry, which is then formed into a sheet to obtain a green sheet.

The binder used may be one that can maintain the shape of the green sheet and volatilizes without leaving carbon or other residues during the binder removal process prior to firing. The binder is such as polyvinyl alcohol, polyvinyl butyral, cellulose, urethane, or vinyl acetate binders. There are no particular restrictions on the amount of binder used, but because it is removed in a later process, it is preferable to use as little as possible while still achieving the desired formability and shape retention, in order to reduce raw material costs.

The dispersant used may be one that does not cause aggregation of the calcined powder and binder and may be easily removed by evaporation or other means after forming into a green sheet, as described below. The dispersant is such as water or alcohol-based solvents.

Components that adjust the properties of the slurry, such as dispersants, plasticizers, and thickeners, may be added to the slurry.

The method for mixing the above mixed powder with the binder and dispersion medium is not particularly limited, as long as it prevents the inclusion of impurities and ensures uniform mixing of the components. One example is ball mill mixing.

Conventional methods, such as the doctor blade method or the die coating method, may be used to form the prepared slurry into a sheet to obtain a green sheet.

((C) Formation of Internal Electrode Pattern)

Next, an internal electrode pattern containing metal is formed on the green sheet. The internal electrode pattern can be formed by printing or applying an internal electrode paste in a predetermined pattern, or by forming a metal film in a predetermined pattern by vapor deposition or sputtering. The internal electrode pattern is formed with a sufficient margin to ensure electrical insulation with the via conductor patterns that will be formed later and that will not come into contact with the via conductor patterns.

When forming the internal electrode pattern using the internal electrode paste, the internal electrode paste used is obtained by mixing metal particles and a vehicle in a triple roll mill. In addition to the components described above, the internal electrode paste may also contain glass frit and ceramic powder.

The type and amount of binder and solvent contained in the vehicle used are not limited and may be selected appropriately taking into consideration the viscosity of the internal electrode paste, ease of handling, and compatibility with the green sheet.

The internal electrode paste may be printed onto the green sheet, for example, using a screen mask with a predetermined internal electrode pattern formed on it. When printing, a space that will become a margin when the multilayer ceramic capacitor is completed may be left open.

### ((D) Fabrication of Green Multilayer Body

Next, a predetermined number of green sheets with internal electrode patterns formed on them are stacked and pressed together to obtain a green multilayer body. Stacking and pressing may be performed using conventional methods, such as pressing the stacked green sheets together in the stacking direction while heating them, and thermocompression bonding using the action of the binder.

### (e) Formation of Through Holes for via Conductors

Next, through holes for via conductors are formed in the green multilayer body. Conventional methods, such as drilling or lasers, may be used to form the holes. Lasers are preferred because they produce a smooth surface. If the end of the enlarged diameter portion or the via conductor cover portion in the final multilayer ceramic capacitor is to have a flange shape, after the through hole is formed, a portion of the raw material for the green multilayer body may be removed from the periphery of one of the openings to form a void shaped to correspond to the flange. The method for removing the green sheet is such as pressing a mold with a convex portion against the periphery of the opening or polishing.

### (F) Stacking of Cover Green Sheet (1)

Next, a cover green sheet, which will become the cover portion when the multilayer ceramic capacitor is completed, is added to at least one surface perpendicular to the stacking direction of the green multilayer body with the via conductor through holes formed. The cover green sheet may have the same composition as or a different composition from the green sheet on which the internal electrode pattern is printed. From the viewpoint of making the shrinkage rate during firing uniform, the composition of the green sheet for the cover portion is preferably the same as or similar to the composition of the green sheet on which the above-mentioned internal electrode precursor is printed.

The cover green sheet added in this step forms the cover in the final multilayer ceramic capacitor, with the via conductors extending to the surface. Therefore, to obtain a multilayer ceramic capacitor in which both ends of the via conductors extend to the surface of the cover, cover green sheets are added to both surfaces perpendicular to the stacking direction of the green multilayer body. On the other hand, to obtain a multilayer ceramic capacitor in which one end of the via conductor is located within the cover, a cover green sheet is stacked on the surface of the one end of the green multilayer body after filling with via conductor paste (G), described below.

The cover green sheet added in this step has through holes with a smaller diameter than the via conductor through holes in the green multilayer body, at positions corresponding to the via conductor through holes. These smaller diameter through holes form the reduced-diameter extensions of the via conductors in the final multilayer ceramic capacitor. The small diameter through holes may be formed using a punching machine or laser processing machine. Alternatively, instead of using green cover sheets with small through holes, green cover sheets without through holes may be stacked, and through holes smaller in diameter than the through holes may be formed in the green multilayer body at positions corresponding to the via conductor through holes. The same method for forming the small through holes may be used as for forming via conductor through holes in the green multilayer body.

(G) Filling with Via Conductor Paste

Next, the through holes are filled with via conductor paste to form a via conductor pattern. Common methods for filling the via conductor paste into the holes such as syringe injection or printing using a metal mask may be used. Among these, printing using a metal mask is preferred due to its excellent ability to fill small holes. The via conductor paste can contain the same components as the internal electrode paste described above, and the amount of each component may be determined based on the hole filling ability. To form a cavity at the end of a via conductor located in the cover, a convex member smaller than the through hole is inserted from the side where the cavity is formed, followed by filling with via conductor paste. The convex member may then be removed, or the through hole may be filled with via conductor paste and the green multilayer body may be vibrated with the side where the cavity is formed facing upward. On the other hand, to form the end of a via conductor located in the cover with a bulging center, the green multilayer body may be filled with via conductor paste so that it protrudes (bulges) beyond the surface height of the green multilayer body.

### (H) Stacking of Green Sheets for Cover (2)

To obtain a multilayer ceramic capacitor in which one end of the via conductor is located in the cover, a green sheet that will become the cover portion when the multilayer ceramic capacitor is made is stacked on the surface of the green multilayer body where the via conductor through hole opens. The green sheet to be stacked may have the same composition as the green sheet that forms the green multilayer body, or a different composition. The stacking method is such as placing the green sheets and then pressing them using a mold, or applying pressure to the green sheets using a roller.

### (I) Formation of Terminal Electrode Pattern

Next, a terminal electrode pattern is formed on at least one of the surfaces of the green multilayer body perpendicular to the stacking direction, where the via conductor pattern is exposed. The terminal electrode pattern may be formed by printing or applying a terminal electrode paste, or by forming a metal film by vapor deposition or sputtering. The terminal electrode pattern may be formed using a mask with a predetermined pattern. Alternatively, the terminal electrode pattern may be formed by first forming a paste or metal film on the entire surface of the green multilayer body where the via conductor pattern is exposed, and then removing the area other than the terminal electrode pattern. Face milling and barrel polishing, for example, may be used to remove the area other than the terminal electrode pattern. When using a terminal electrode paste to form the terminal electrode pattern, the components may be the same as those of the internal electrode paste described above. The blending amounts of each component may be determined to obtain a uniform pattern with the desired thickness.

### (J) Pre-fired Chip Fabrication

Next, the green multilayer body is cut into individual multilayer ceramic capacitor shapes to obtain pre-fired chips. A conventional method such as a dicing saw or a laser cutter may be used. After cutting the green multilayer body to form surfaces on which the internal electrode precursors are exposed, the surfaces on which the internal electrode precursors are exposed may be coated with a material for forming margins to produce pre-fired chips.

### (K) Binder Removal

Next, the resulting pre-fired chips are heated to volatilize and remove the binder. The heating conditions may be set appropriately, taking into account the binder's volatilization temperature and content. One example is holding the chips in a nitrogen (N₂) atmosphere at a temperature between 200° C. and 500° C. for 5 to 20 hours.

### (L) Pre-fired Chip Firing

Next, the pre-fired chips from which the binder has been removed are heated to a predetermined temperature and fired. When setting the firing conditions, it is preferable to take into consideration the sinterability of the ceramic powder, as well as the heat resistance and oxidation resistance of the metals contained in the internal electrode pattern, the via conductor pattern, and the terminal electrode pattern. An example of firing conditions is holding the material at a temperature of 1100° C. to 1400° C. for 10 minutes to 2 hours in a reducing atmosphere containing a mixture of nitrogen (N₂), hydrogen (H₂), and water vapor (H₂O). After firing, a re-oxidation treatment may be performed by holding the material at 600° C. to 1000° C. in a nitrogen (N₂) gas atmosphere or a low-oxygen atmosphere.

The sintered body obtained in this manner may be used as a multilayer ceramic capacitor as is, or it may be used after forming a conductive layer on the surface of the terminal electrode pattern by plating.

To obtain a preferred embodiment of the multilayer ceramic capacitor according to the first aspect in which a metal element isolation portion is present near the diameter-reduced extension portion in the cover portion, the order of steps (F) and (G) described above is first reversed. After step (F), a paste for forming a metal element isolation portion, prepared by mixing a material for forming a cover portion with a material for forming a via conductor, is applied to the inner peripheral wall of a recess present on the surface of the green multilayer body on the side of the green sheet for the cover portion. The center of the recess is then filled with the paste for forming a via conductor, and the processes from step (H) onward are carried out. In this case, the through holes formed in the green sheet for the cover portion used in step (F) are reduced in diameter by the application of the paste for forming a metal element isolation portion, and therefore may have the same diameter as the through holes for the via conductors formed in the green multilayer body, or may have a larger diameter.

### Circuit Board

The circuit board according to the second aspect of the present invention is equipped with the multilayer ceramic capacitor according to the first embodiment. Because the multilayer ceramic capacitor is thin and suppresses electrostatic capacity degradation, this circuit board is highly reliable and can be installed in small spaces.

Although the embodiments of the present invention have been described in detail, it is to be understood that the various change, substitutions, and alterations could be made hereto without departing from the spirit and scope of the invention.

What is claimed is:

1. A multilayer ceramic electronic component comprising:
a multilayer body having a plurality of internal electrodes facing each other in a stacking direction and ceramic layers disposed between the plurality of internal electrodes;
a protective portion that covers a surface of the multilayer body;
an element body having a rectangular parallelepiped shape and having a plurality of via conductors disposed to penetrate the ceramic layers in the stacking direction of the multilayer body, at least one end of which is extended to a surface of the protective portion and is electrically connected to at least a part of the plurality of internal electrodes; and
a plurality of terminal electrodes, which are arranged at least on surfaces forming the surface of the element body from which ends of the via conductors are drawn out, and which are electrically connected to at least one of the plurality of via conductors;
wherein the via conductor comprises:
a reduced diameter extension portion that extends through the protective portion to the surface of the protective portion and has a dimension in a direction perpendicular to the stacking direction of the multilayer body that is smaller than a minimum dimension obtained in a multilayer body internal region, which is a region inside a fifth internal electrode layer counted from the protective portion side of the multilayer body; and
an enlarged diameter portion formed in the protective portion in which the reduced diameter extension portion is arranged, or in a multilayer body external region located between the protective portion in which the reduced diameter extension portion is arranged and a multilayer body internal region, the enlarged diameter portion having a dimension in a direction perpendicular to the stacking direction of the multilayer body larger than a maximum dimension obtained in the multilayer body internal region.

2. The multilayer ceramic electronic component as claimed in claim 1,
wherein a maximum dimension of the enlarged diameter portion in a direction perpendicular to the stacking direction of the multilayer body is 1.2 times or more a minimum dimension of the reduced diameter stretched portion in a direction perpendicular to the stacking direction of the multilayer body.

3. The multilayer ceramic electronic component as claimed in claim 1,
wherein the enlarged diameter portion forms a flange that projects outward relative to an axis of the via conductor.

4. The multilayer ceramic electronic component as claimed in claim 3,
wherein a dimension A1 of the flange formed by the enlarged diameter portion in the stacking direction is 0.1 μm or more and 10 μm or less.

5. The multilayer ceramic electronic component as claimed in claim 1,
wherein, in the protective portion through which the reduced diameter extension portion passes, a metal element isolation portion is present near the reduced diameter extension portion, in which a concentration of a same metal element as a main component element of the via conductor is higher than that of a surrounding area.

6. The multilayer ceramic electronic component as claimed in claim 1,
wherein the via conductor has an end opposite to the reduced diameter extension portion disposed in the protective portion, and the end forms a flange that projects outward relative to an axis of the via conductor.

7. The multilayer ceramic electronic component as claimed in claim 1,
wherein, when a dimension of the multilayer body internal region in a direction perpendicular to the stacking direction of the multilayer body at an end of the reduced diameter extension portion side is D1, and a dimension of the multilayer body internal region in the direction perpendicular to the stacking direction of the multilayer body at an end on an opposite side to the reduced diameter extension portion is D2, the via conductor satisfies D1>D2, and a dimension of the via conductor in the direction perpendicular to the stacking direction monotonically decreases from D1 to D2.

8. The multilayer ceramic electronic component as claimed in claim 7,
wherein, when a dimension of a flange formed by the end on the opposite side to the reduced diameter extension portion in the direction perpendicular to the stacking direction is defined as D3, the via conductor satisfies D3≥D1.

9. The multilayer ceramic electronic component as claimed in claim 6,
wherein, in the via conductor, a dimension A2 of the flange formed by the end on the opposite side to the reduced diameter extension portion is 0.1 μm or more and 10 μm or less in the stacking direction.

10. The multilayer ceramic electronic component as claimed in claim 6,
wherein the via conductor has a cavity that opens to the end on the opposite side to the reduced diameter extension portion.

11. The multilayer ceramic electronic component as claimed in claim 1,
wherein a dimension of the multilayer ceramic electronic component in the stacking direction is 100 μm or less 12. A circuit board comprising:
a board; and
a multilayer ceramic electronic component claimed in claim 1 mounted on the board.
